(19) United States
(12) Patent Application Publication
(10) Pub. No.: US 2013/0126346 A1
(43) Pub. Date: May 23, 2013

(54) CHALCOGENIDE ALLOY SPUTTER TARGETS FOR PHOTOVOLTAIC APPLICATIONS AND METHODS OF MANUFACTURING THE SAME

(71) Applicant: ZETTA RESEARCH AND DEVELOPMENT LLC- AQT SERIES, Wilmington, DE (US)

(72) Inventors: Brian Josef BARTHOLOMEUSZ, Palo Alto, CA (US); Michael BARTHOLOMEUSZ, Phoenix, AZ (US)

(73) Assignee: ZETTA RESEARCH AND DEVELOPMENT LLC - AQT SERIES, Wilmington, DE (US)

(21) Appl. No.: 13/744,020

(22) Filed: Jan. 17, 2013

Related U.S. Application Data
(63) Continuation of application No. 12/606,709, filed on Oct. 27, 2009, now abandoned.
(60) Provisional application No. 61/110,520, filed on Oct. 31, 2008.

(51) Int. Cl. C23C 14/34

(52) U.S. Cl. CPC C23C 14/3414
USPC 204/298.13

(57) ABSTRACT

In one example embodiment, a sputter target structure for depositing semiconducting chalcogenide films is described. The sputter target includes a target body comprising at least one chalcogenide alloy having a chalcogenide alloy purity of at least approximately 2N7, gaseous impurities less than 500 ppm for oxygen (0), nitrogen (N), and hydrogen (H) individually, and a carbon (C) impurity less than 500 ppm. In a particular embodiment, the chalcogens of the at least one chalcogenide alloy comprises at least 20 atomic percent of the target body composition, and the chalcogenide alloy has a density of at least 95% of the theoretical density for the chalcogenide alloy.

### RELATED APPLICATIONS

This application is a continuation of U.S. patent application Ser. No. 12/606,709, filed Oct. 27, 2009, which claims the benefit, under 35 U.S.C. §119(e), of U.S. Provisional Patent Application No. 61/110,520, entitled CHALCOGENIDE ALLOY SPUTTER TARGETS FOR PHOTOVOLTAIC APPLICATIONS AND METHODS OF MANUFACTURING THE SAME, filed 31 Oct. 2008, and hereby incorporated by reference herein. This application is also related to international PCT application No. PCT/US2007/082405 (Pub. No. WO/2008/052067), entitled SEMICONDUCTOR GRAIN AND OXIDE LAYER FOR PHOTOVOLTAIC CELLS, filed Oct. 24, 2007, and hereby incorporated by reference herein.

### TECHNICAL FIELD

The present disclosure generally relates to sputter targets suitable for use in depositing semiconducting chalcogenide films.

### BACKGROUND

Semiconducting Chalcogenide films are typically used as absorber layers in photovoltaic devices, such as solar cells. A chalcogenide is a chemical compound consisting of at least one chalcogen ion (group 16 (VI) elements in the periodic table, e.g., sulfur (S), selenium (Se), and tellurium (Te) and at least one more electropositive element. As those of skill in the art will appreciate, references to Chalcogenides are generally made in reference to Sulfides, Selenides, and Tellurides only. Thin film based solar cell devices may utilize these Chalcogenide semiconductor materials as the absorber layer as is or, alternately, in the form of an alloy with other elements or even compounds like oxides, nitrides and carbides, among others. Chalcogenide (both single and mixed) semiconductors have optical band gaps well within the terrestrial solar spectrum, and hence, can be used as photon absorbers in thin film based solar cells to generate electron hole pairs and convert light energy to usable electrical energy.

Physical vapor deposition based processes, and particularly sputter based deposition processes, have conventionally been utilized for high volume manufacturing of such thin film layers with high throughput and yield. These thin film layers can be deposited by the sputtering (in the form of reactive In on-reactive or co-sputtering) of high purity sputter targets. Generally, the quality of the resultant semiconductor thin films depends on the quality of the sputter target supplying the material which, similarly, generally depends on the quality of the target's fabrication. Providing manufacturing simplicity while ensuring exact stoichiometry control can ideally be achieved by non-reactive sputter of high purity sputter targets of the appropriate materials having the same stoichiometry. However, as some of these materials have different atomic specie with varying sputter rates as well as different melting points, achieving the exact desired stoichiometry in the thin film presents a challenge. As those of skill in the art will appreciate, any non-stoichiometry in the resultant thin film can contribute to non-adjusted charge compensations in the structure and can affect the device characteristics. Additionally, the incorporation of impurities from the sputter targets into the thin film absorber layers can also cause inconsistent and unreliable device characteristics. By way of example, impurities can act as trap levels (which would vary based on different impurities and their relative concentrations) in the band gap. Furthermore, the sputter targets themselves need to have adequate density in order to minimize arcing and defect generation during the deposition process, as these can limit the process yield.

### BRIEF DESCRIPTION OF THE DRAWINGS

FIG. 1 is a flowchart illustrating an example process for manufacturing an example sputter target.

FIG. 2 is a flowchart illustrating an example process for manufacturing an example sputter target.

FIG. 3 is an example plot showing the atomic percent or eight percent of selenium as a function of temperature in degrees Celsius.

FIG. 4 is an example plot showing the atomic percent or weight percent of indium as a function of temperature in degrees Celsius.

FIGS. 5A and 5B illustrate diagrammatic top and cross-sectional side views, respectively, of an example sputter target.

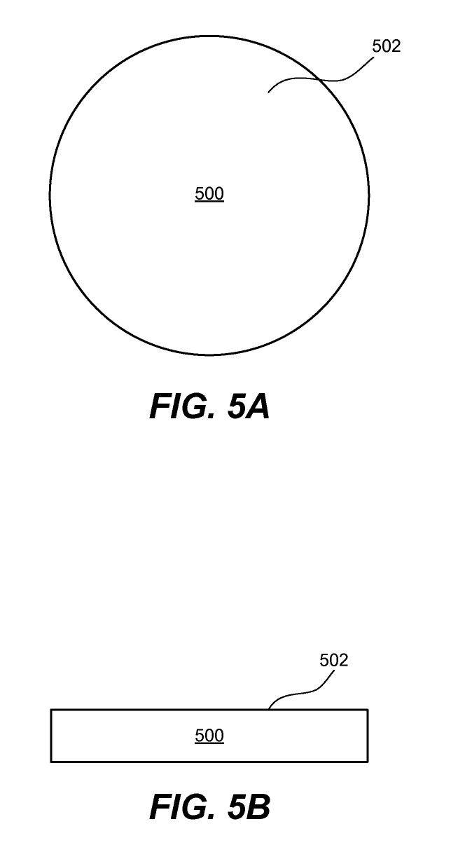

### DESCRIPTION OF EXAMPLE EMBODIMENTS

Particular embodiments of the present disclosure are related to sputter targets for depositing semiconducting chalcogenide films and methods of fabricating such targets. Specifically, one aspect relates to providing high density, low impurity sputter target solutions for chalcogenide (single or mixed) semiconducting materials for deposition of stoichiometric, low impurity, high density thin film absorber layers for photovoltaic device applications, and particularly, thin film based solar cells. The following description provides multiple example embodiments of process routes based on ingot and powder metallurgical techniques in manufacturing such sputter targets.

In various embodiments, the semiconducting thin films resulting from the sputtering of such targets may be either intrinsic semiconductors or extrinsic semiconductors. By way of example, the thin films may be extrinsic when doped with elements such as phosphorus (P), nitrogen (N), boron (B), arsenic (As), and antimony (Sb). In some particular embodiments, the semiconducting chalcogenides may also be utilized along with semiconducting or insulating oxides, nitrides, carbides and/or borides, among others, as for example described in PCTIUS2007/082405 (Pub. No. W0/2008/052067) filed Oct. 24, 2007 and entitled SEMICONDUCTOR GRAIN AND OXIDE LAYER FOR PHOTOVOLTAIC CELLS, which is incorporated by reference herein. In such embodiments, the film microstructure becomes granular with the oxides, nitrides, carbides and/or borides, etc. making the grain boundary phase.

The sputter targets manufactured in accordance with particular embodiments contain chalcogenide alloys or compounds with particular purity, density and microstructure properties or requirements. By way of example and not by way of limitation, the compositions of the manufactured sputter targets may be comprised of various chalcogenides including: mercury telluride (HgTe), led sulfide (PbS), led selenide (PbSe), led telluride (PbTe), cadmium sulfide (CdS), cadmium selenide (CdSe), cadmium tellurium (CdTe), zinc sulfide (ZnS), zinc selenide (ZnSe), zinc telluride (ZnTe), tin telluride (SnTe), copper sulfide (e.g., CuS, Cu2S, or CUl-xSx (e.g., where x may vary from 0 to 1)), copper selenide (e.g., CuSe, Cu2Se, CuSe2, or CU2-xSel+x (e.g., where x may vary from 0 to 1)), copper indium disulfide (CuInS2), copper gallium disulfide (CuGaS2), copper indium gallium disulfide, (Cu(Inl-xGax)S2 (e.g., where x may vary from 0 to 1)), copper indium diselenide (CuInSe2), copper gallium diselenide (CuGaSe2), copper indium gallium diselenide (Cu(Inl-xGax)Se2 (e.g., where x may vary from 0 to 1)), copper silver indium gallium disulfide (Cul-xAgx)(Inl-yGay)S2 (e.g., where x may vary from 0 to 1 and y may vary from 0 to 1)), copper silver indium gallium diselenide (Cul-xAgx)(Inl-yGay)Se2 (e.g., where x may vary from 0 to 1 and y varies from 0 to 1)), indium sulfide (In2S3), (In2S3)x(Ga2S3)l-x (e.g., where x may vary from 0 to 1, and, particularly, where x is approximately equal to 0.2, 0.35, 0.5, 0.75 or 0.8), indium selenide (In2Se3), (In2Se3)x(Ga2Se3)l-x (e.g., where x may vary from 0 to 1, and, particularly, where x is approximately equal to 0.2, 0.35, 0.5, 0.75 or 0.8), bismuth sulfide (BhSe3), antimony sulfide (Sb2S3), silver sulfide (Ag2S), tungsten sulfide (WS2), tungsten selenide (WSe2), molybdenum sulfide MOS2), molybdenum selenide (MoSe2), tin sulfide (SnSx (e.g., where x may vary from 1 to 2)), tin selenide (SnSex (e.g., where x may vary from 1 to 2)), copper tin sulfide (CU4SnS4), among others.

The sputter targets and resultant desired semiconducting thin films deposited with such sputter targets produced according to example embodiments described herein may include only a single chalcogenide or, alternately, multiple chalcogenides. A mixed chalcogenide thin film may be produced using either a single sputter target that includes multiple chalcogenides or, alternately, a plurality of sputter targets each containing one or more chalcogenides produced according to the processes described herein. It should be noted that the number, types and specific combinations of such different chalcogenides may vary widely in various embodiments. However, in particular embodiments, the concentrations of the chalcogens (e.g., S, Se and/or Te) are at least 20 atomic percent in the sputter target chalcogenide alloy compositions.

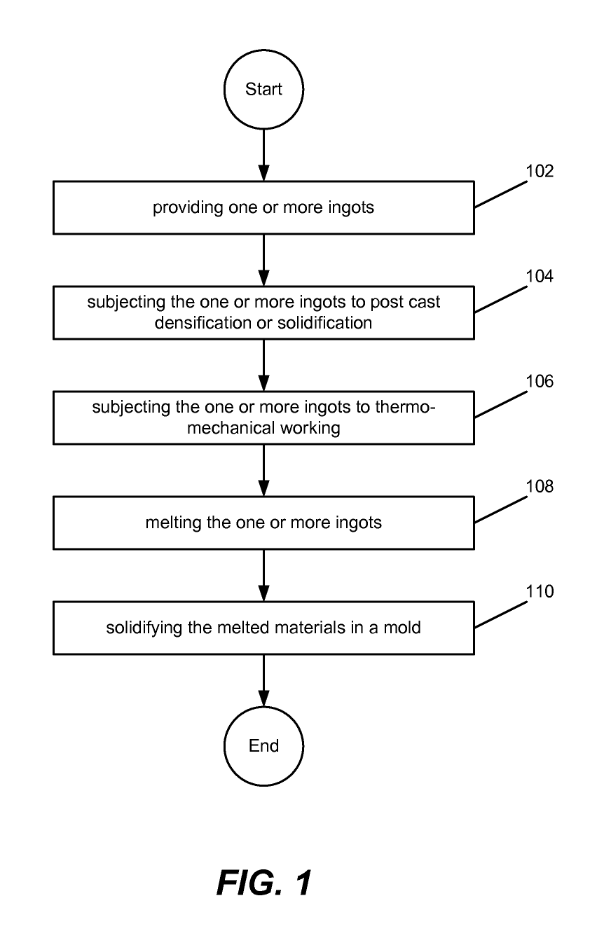

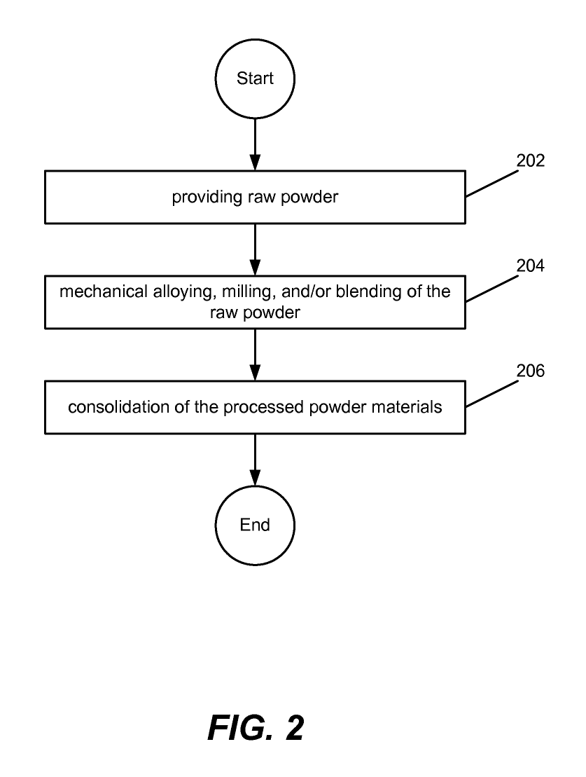

Two example processes for manufacturing sputter targets, such as the aforedescribed sputter targets, will now be described with initial reference to FIGS. 1 and 2. Based on the purity, density, microstructure and compositional requirements of a particular application, the sputter targets may be manufactured using: (1) ingot metallurgy, as described and illustrated, by way of example and not by way of limitation, with reference to the flowchart of FIG. 1; or (2) powder metallurgy, as described and illustrated, by way of example and not by way of limitation, with reference to the flowchart of FIG. 2. It should be noted that the processes described with reference to FIGS. 1 and 2 may each actually include one or more separate processes although the processes described with reference to FIGS. 1 and 2 are each described and illustrated in conjunction with a single flowchart.

In particular embodiments, ingot metallurgy may be used for producing sputter targets having alloy compositions containing single or mixed chalcogenides with or without added doping elements (e.g., phosphorus (P), nitrogen (N), boron (B), arsenic (As), or antimony (Sb)). In particular embodiments, the process illustrated with reference to FIG. 1 begins with providing one or more ingots at 1 02 that collectively contain the material(s) (e.g., elemental or master alloys) of which the resultant sputter target(s) are to be comprised (e.g., one or more ingots that each contain the materials for producing a sputter target having a desired chalcogenide alloy composition, or alternately, two or more ingots that collectively, but not individually, contain the materials for producing the sputter target having the desired chalcogenide alloy composition).

As the chalcogenides are line compounds, they are typically brittle; however, any gas or shrinkage porosities can be prevented using solidification of the ingot(s) at a very controlled rate (e.g., a cooling rate less than approximately 1000 degrees Celsius per minute). In particular embodiments, the density of as-cast ingots can be enhanced through post casting densification of the ingots using, by way of example, hot isostatic pressing and/or other consolidation methods using ambient or elevated temperatures and pressures. Based on the ductility and workability of the alloy, such ingots can be also be subjected in some particular embodiments to thermomechanical working to further enhance the density and refine the as-cast microstructure. Alloy compositions containing low melting elements, such as Ga, or alloys containing any low melting phases formed during solidification, may have limited process windows.

In one example embodiment, the afore-described sputter targets may be manufactured using as-cast ingots as provided at 102. However, in some particular embodiments, as described above, the as-cast ingots may be subjected to post cast densification or solidification at 104. By way of example, post cast densification of the as-cast ingots at 104 may be achieved by hot isostatic pressing at ambient or elevated temperatures and pressures. In still other embodiments, the as-cast ingots may be subjected to post cast densification at 104 followed by thermomechanical working at 106. Examples of thermo-mechanical working include, by way of example and not by way of limitation, uni- or multi-directional cold, warm or hot rolling, forging, or any other deformations processing at temperatures ranging, by way of example, from ambient to approximately 50 degrees Celsius lower than the solidus temperature.

In particular example embodiments, the ingots are then melted at 108 using, by way of example, vacuum or inert gas melting (e.g., induction, e-beam melting) at temperatures of, by way of example, up to approximately 200 degrees Celsius above the liquidus in vacuum (at less than approximately 1 Torr). In alternate embodiments, the ingots may be melted in open melters. In either case, the process may then proceed with controlled solidification at 11 0 (e.g., conventional or assisted by stirring or agitation) in a mold with a cooling rate of, by way of example, less than approximately 1000 degrees Celsius per minute. This allows sufficient time to remove impurities in the form of low density slags. Exact stoichiometry control can be ensured even for alloys containing low melting high vapor pressure elements (like Ga), by maintaining a positive inert gas pressure (e.g., greater than 0.01 milliTorr) during melting at 108 and solidification at 110. The resultant sputter target bodies may then be machined among other conventional processing.

According to particular embodiments, sputter targets containing single or mixed chalcogenides, where the chalcogens, particularly S, Se and/or Te, comprise at least 20 atomic percent in the sputter target chalcogenide alloy compositions, can be formed with ingot metallurgical techniques as just described with reference to FIG. 1 with sputter target purities of 2N7 and greater (e.g., the chalcogenide alloy(s) of the sputter target are at least 99.7% pure), and with gaseous impurities less than 500 parts-per-million (ppm) for oxygen (0), nitrogen (N), hydrogen (H) individually and low carbon (C) levels (e.g., less than 500 ppm). Additionally, in particular embodiments, the resultant sputter targets can be formed with chalcogenide ahoy densities in excess of 95% of the theoretical density for the alloy. Furthermore, chalcogenide alloy sputter targets may be formed with microstructures showing mostly equiaxed (>60% by volume) grains (with grain aspect ratios less than 3.5). In most alloys, the columnarity (aspect ratio) in the target microstructure from an as-cast ingot may be removed during machining. In some embodiments, the above microstructural features can also be obtained using stirring or agitating the melt during the solidification process, breaking any columnarity in the microstructure by shear forces. Additionally, it should also be appreciated that ingot metallurgy derived targets can be recycled as remelts. This reduces their cost of ownership quite significantly.

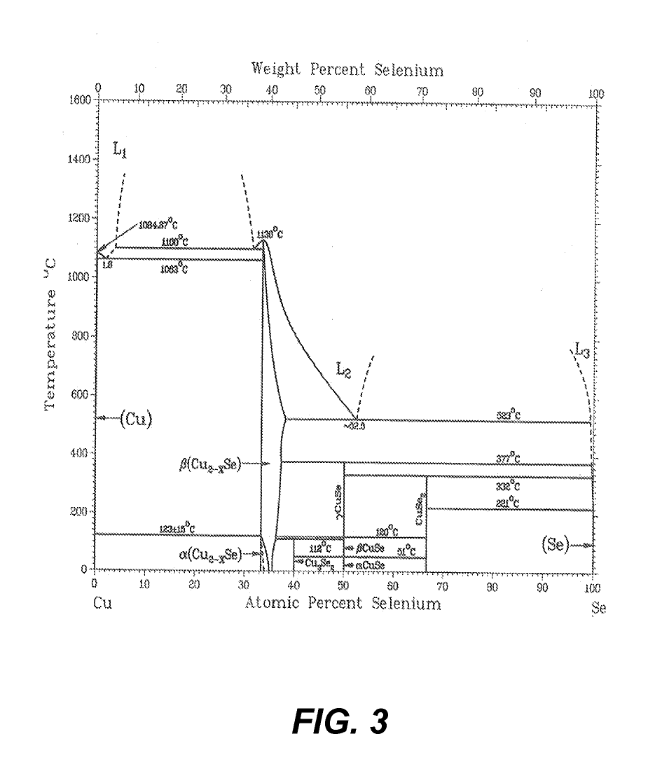

In a specific example embodiment of a ingot metallurgical process, a CuSe sputter target is manufactured using ingot melt stocks (elemental or remelt stocks) in a vacuum melter (base pressure˜0.8 Torr) at 725 degrees Celsius (e.g., above 200 degrees Celsius over the liquidus), followed by controlled solidification (e.g., at a cooling rate less than approximately 1000 degrees Celsius per minute). The as-cast ingot is cross-rolled (at 30 degree Celsius intervals), while the temperature at the surface of the ingot is in the range of approximately 100-250 degrees Celsius, and in a particular embodiment, at least 50 degrees Celsius below the solidus temperature. Spent targets of this alloy composition can also be used as remelt stocks. FIG. 3 is a plot of the atomic percent or weight percent of Se as a function of temperature in degrees Celsius.

A second process for forming sputter targets using powder metallurgy will now be described with reference to the flowchart of FIG. 2. In an example embodiment, powder metallurgy may be utilized for sputter target alloy compositions containing single or mixed chalcogenides with or without doping elements. Again, in particular embodiments, the chalcogens, particularly S, Se and/or Te, comprise at least 20 atomic percent in the sputter target alloy compositions. Generally, alloy compositions that, in addition to the single or mixed chalcogenide, also contain oxides, nitrides, carbides and/or borides, can only be manufactured using the powder metallurgical techniques.

In particular embodiments utilizing powder metallurgy, the sputter targets are manufactured using raw powder(s) provided at 202 followed by mechanical alloying and/or milling (high or low energy) and/or blending of the raw powder (elemental or gas atomized master alloys) at 204, which is then followed by consolidation at 206 in, by way of example, a mold at high pressures and/or temperatures. In particular example embodiments, utilizing judicial selection of raw materials and/or consolidation methods, sputter targets may be formed with chalcogenide alloy densities greater than or equal to approximately 95% of the theoretical density of the alloy. By way of example and not by limitation, example techniques for consolidation at 204 may include one or more of: vacuum hot pressing, hot isostatic pressing, conventional (thermal) sintering (liquid or solid state) or energy assisted (electric) sintering processes. An example of energy assisted sintering is spark plasma sintering. In one example embodiment, alloy compositions containing low melting elements (e.g., a melting point less than 300 degrees Celsius) such as In, Ga, or other suitable element are consolidated at 204 using liquid phase sintering processes. A suitable sintering temperature may, for example, be in the range of approximately 0.2 Tm to 0.8 Tm, where Tm is the melting temperature of the alloy (typically estimated by DTA analysis) or 0.2 Ts to 0.8 Ts. where Ts is the sublimation temperature of any of the chemical components in the alloy.

In particular embodiments, sputter targets made using powder metallurgy as described with reference to FIG. 2 show an average feature size of the largest microstructural feature less than 1000 microns. Furthermore, the microstructure can de designed accordingly by suitable selection of the starting raw powder(s), the respective particle sizes and their distribution and specific surface areas. In a particular embodiment, the ratio of the particle sizes of any two component powders is in the range of approximately 0.01 to 10.

Particular embodiments utilize the mechanical alloying of elemental powders of different atomic specie. Alternate embodiments may utilize rapidly solidified (gas atomized) or meltcrushed master alloys of the exact nominal composition of the chalcogenide in the desired thin film. Still other embodiments may utilize a judicial selection of one or multiple master alloys in combination with another single metal or another master alloy. In particular example embodiments, the master alloys can be designed to enhance the electrical conductivity of the resultant sputter target. This may be specifically useful for Ga, In, or other low melting point metal containing alloys, where the low melting metal may be pre-alloyed and may be processed over a much wider process window.

According to particular embodiments, example sputter targets manufactured according to the powder metallurgical techniques described with respect to FIG. 2 may contain single or mixed chalcogenides with or without oxides, nitrides or borides, etc., where S, Se and/or Te comprise at least 20 atomic percent, with chalcogenide ahoy purities of 2N7 or greater (e.g., the chalcogenide alloy(s) of the sputter target are at least 99.7% pure), gaseous impurities less than 1 000 ppm for 0, N, H Individually, and carbon (C) levels less than 1500 ppm.

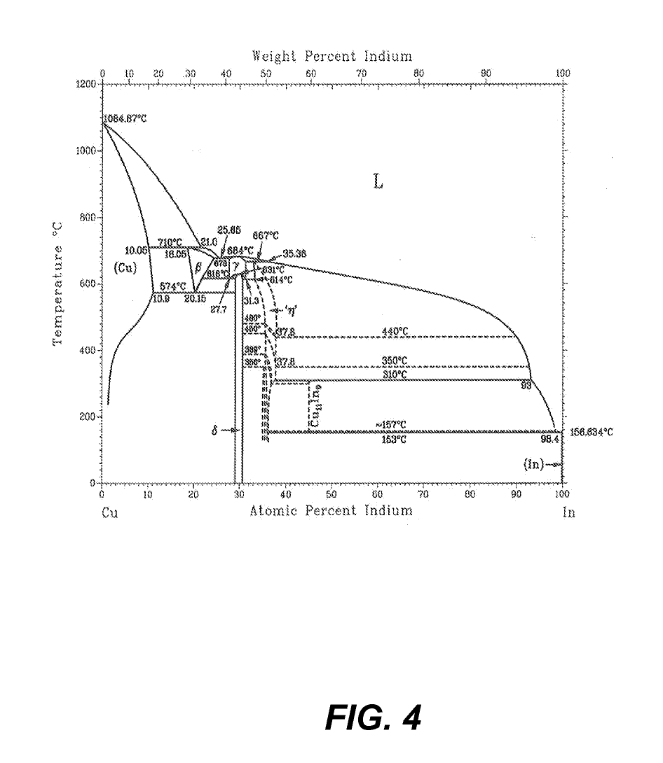

In one specific example embodiment, a CuInSe2 sputter target is manufactured using conventional sintering of Cu, In and Sc powder. In an alternate example embodiment, the sputter target is formed using a CuIn master alloy and Se. In still another example embodiment, the sputter target is formed using a CuSe master alloy and In. The sintering may be performed, by way of example, at a temperature of approximately 400 degrees Celsius using a conventional furnace for approximately 3 hours and then cooled to room temperature. As this sintering temperature is higher than the melting temperatures of Se and In, densification happens with liquid phase sintering. The D50 ratio of the Cu, In and Se powder or the respective master alloys may vary in various embodiments between approximately 0.01-10. FIG. 4 is a plot of the atomic percent or weight percent of indium as a function of temperature in degrees Celsius.

The target body of the resultant sputter targets manufactured according to the described embodiments may, by way of example and not by way of limitation, be a single body of the nominal composition, such as that illustrated in Figures SA and 5B, or a bonded assembly where the target body of the intended nominal composition is bonded to a backing plate using bonding processes employing, by way of example, any or all of adhesive (polymeric or non-polymeric), diffusion bonding, solder bonding or other suitable material joining processes. The target body or target bonded assembly may be disk-shaped, circular, or elliptical in cross section in some particular embodiments. Figures SA and 5B illustrate diagrammatic top and cross-sectional side views, respectively, of an example sputter target 500 having a top sputtering surface 502. In alternate embodiments, the target body or target bonded assembly may take the form of a cylindrical solid with a circular OD (outer diameter) and/or a circular ID (inner diameter), which may also be used as a rotatable assembly in the PVD tool. In still other embodiments, the sputter target may take the form of a rectangular or square piece in which the target body of the intended nominal composition can be a monolithic body or an assembly of several monoliths or tiles. The target body may be used to deposit sputter films on substrates over an area of, by way of example, approximately 2025 square mm and greater. Although target sizes may vary widely and would generally be dependent on applications such as, by way of example, typical PV applications, in particular embodiments the target bodies would be large enough to deposit films uniformly over cells with areas of approximately 156 sq mm and larger and modules in the range of 1.2 square meters.

The present disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend.

What is claimed is:

1. A sputter target structure for depositing semiconducting chalcogenide films, comprising:
a target body comprising at least one chalcogenide alloy having a chalcogenide alloy purity of at least approximately 2N7, gaseous impurities less than 500 parts-per-million (ppm) for oxygen (0), nitrogen (N), and hydrogen (H) individually, and a carbon (C) impurity less than 500 ppm, wherein the chalcogens of the at least one chalcogenide alloy comprise at least 20 atomic percent of the target body composition, and wherein the at least one chalcogenide alloy has a density of at least 95% of the theoretical density for the chalcogenide alloy.
